(19) United States
(12) Patent Application Publication
(10) Pub. No.: US 2014/0291688 A1
(43) Pub. Date: Oct. 2, 2014

(54) ACTIVE MATRIX SOLID STATE LIGHT DISPLAY

(71) Applicant: HON HAI PRECISION INDUSTRY CO., LTD., New Taipei (TW)

(72) Inventor: JIAN-SHIHN TSANG, Tu-Cheng (TW)

(73) Assignee: HON HAI PRECISION INDUSTRY CO., LTD., New Taipei (TW)

(21) Appl. No.: 14/219,015

(22) Filed: Mar. 19, 2014

(30) Foreign Application Priority Data
Mar. 29, 2013 (TW) 102111280

(51) Int. Cl. H01L 27/12

(52) U.S. Cl. CPC H01L 27/1214
USPC 257/72

(57) ABSTRACT

An exemplary active matrix solid state light display includes a substrate, a plurality of solid state lighting elements and a plurality of thin film transistors. A buffer layer is formed on the substrate. The solid state lighting elements are formed on the buffer layer, and the thin film transistors are formed on the substrate. The thin film transistor is located at a lateral side of the solid state lighting element. The solid state lighting element is a light emitting diode. The thin film transistor electrically connects with the solid state lighting element by a way of a source electrode or a drain electrode connecting with the solid state lighting element.

### BACKGROUND

1. Technical Field

This disclosure generally relates to solid state light displays, and particularly to an active matrix solid state light display comprising solid state lighting elements having stable and reliable performance.

2. Description of Related Art

A typical active matrix organic light emitting display (AMOLED) includes a plurality of organic light emitting elements functioning as light sources. However, in a manufacturing process of the active matrix organic light emitting display, the organic light emitting materials are prone to be affected by environmental factors, such as moisture, which cause the organic materials to be deteriorated. Therefore, manufacturing process of the active matrix organic light display need to be performed in a vacuum environment to avoid the deterioration of the organic materials, resulting in a complicated manufacturing process. In addition, the deterioration of the organic light emitting materials shortens the service life of the active matrix organic light displays.

What is needed, therefore, is an active matrix solid state light display which can overcome the above-described shortcoming.

### BRIEF DESCRIPTION OF THE DRAWINGS

FIG. 1 is a cross-sectional view of an active matrix solid state light display according to a first embodiment of the present disclosure.

FIG. 2 is a cross-sectional view of an active matrix solid state light display according to a second embodiment of the present disclosure.

FIG. 3 is a cross-sectional view of an active matrix solid state light display according to a third embodiment of this disclosure.

FIG. 4 is a cross-sectional view of an active matrix solid state light display according to a fourth embodiment of this disclosure.

### DETAILED DESCRIPTION

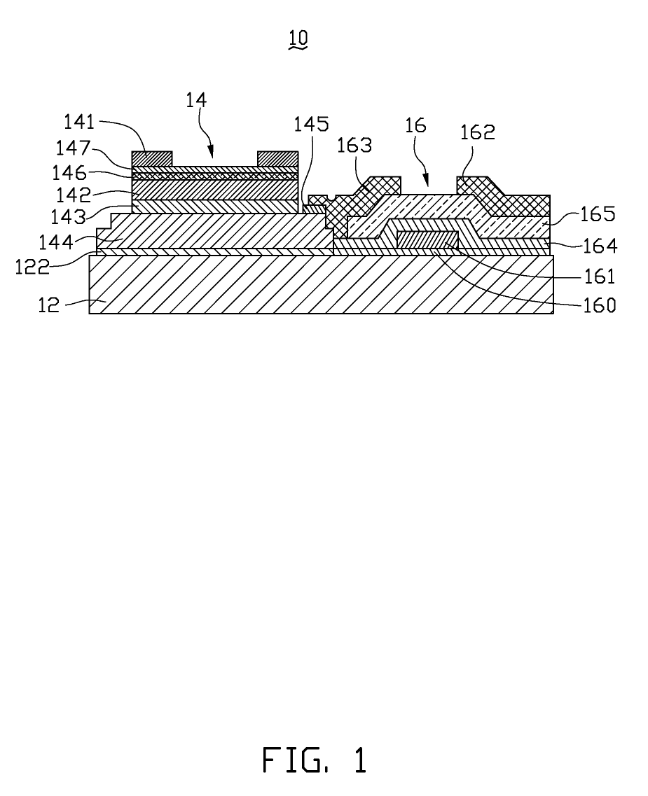

Referring to FIG. 1, an active matrix solid state light display 10 in accordance with a first embodiment of the present disclosure is provided.

The active matrix solid state light display 10 includes a substrate 12, a plurality of solid state lighting elements 14, and a plurality of thin film transistors 16. In this figure, only one solid state lighting element 14 and one thin film transistor 16 are shown.

The substrate 12 is made of sapphire, silicon, silicon on insulator (SOI), glass, GaN, ZnO or plastic. A buffer layer 122 is formed on a top surface of the substrate 12. The buffer layer 122 is electrically insulated. The buffer layer 122 is made of at least one of LT-AlInGaN (Low Temperature AlInGaN), SiOₓ, SiNₓ, SiON, HfOₓ, AlOₓ, TaOₓ, or BaSrTiOₓ.

The solid state lighting elements 14 are formed on the buffer layer 122, and the thin film transistors 16 are formed on the substrate 12. The solid state lighting elements 14 each are a light emitting diode (LED). The solid state lighting element 14 can be selected from an oxide semiconductor, a nitride semiconductor, a phosphide semiconductor, or an arsenide semiconductor. The solid state lighting element 14 may be a compound semiconductor, including III-V semiconductors, II-VI semiconductors, or IV-IV semiconductors. In this embodiment, the solid state lighting element 14 is a P-N type light emitting diode, and includes a p-type electrode 141, a p-type semiconductor layer 142, a light emitting layer 143, an n-type semiconductor layer 144 and an n-type electrode 145.

The n-type semiconductor layer 144 is formed on the buffer layer 122. The light emitting layer 143 is formed on the n-type semiconductor layer 144. The p-type semiconductor layer 142 is formed on the light emitting layer 143. The n-type electrode 145 is formed on the n-type semiconductor layer 144. The p-type electrode 141 and the n-type electrode 145 are metal blocks or thin metal films, and are used to electrically connect with the thin film transistor 16.

A contact layer 146 and a current spreading layer 147 are located between the p-type semiconductor layer 142 and the p-type electrode 141. The current spreading layer 147 is a low contact resistant layer to help the contact layer 146 spread the current, which increases the lighting efficiency of the solid state lighting element 14.

The n-type semiconductor layer 144 can be a metal oxide semiconductor, such as ZnO or IGZO, or a compound semiconductor, such as ZnSe, GaAs, InGaAlP or AlInGaN. In this embodiment, the n-type semiconductor layer 144 may be a transparent metal oxide semiconductor, and it may electrically connect with the thin film transistor 16. The light emitting layer 143 of the solid state lighting element 14 is made of CdZnMgSeTe, AlGaInP, AlInGaAs, AlInGaN, ZnO, IGZO, or SiGe.

The thin film transistor 16 is located at a lateral side of the solid state lighting element 14. The thin film transistor 16 includes a gate electrode 161, a source electrode 162, and a drain electrode 163. An insulation layer 160 is formed on the substrate 12. The gate electrode 161 is formed on the insulation layer 160. A gate insulation layer 164 is formed on the gate electrode 161. The gate insulation layer 164 covers the gate electrode 161 therein. The source electrode 162 and the drain electrode 163 are located above the gate electrode 161.

An active layer 165 is formed on the gate insulation layer 164 and is located between the gate electrode 161 and the source electrode 162. The source electrode 162 and the drain electrode 163 are formed on the active layer 165.

The gate insulation layer 164 insulates the gate electrode 161 and the source electrode 162, and also insulates the gate electrode 161 and the drain electrode 163. The thin film transistor 16 can electrically connect with the solid state lighting element 14 by the source electrode 162 or the drain electrode 163.

In the first embodiment, the source electrode 162 or the drain electrode 163 of the thin film transistor 16 electrically connects with the solid state lighting element 14 by the n-type semiconductor layer 144. When the n-type electrode 145 is formed on the n-type semiconductor layer 144, the source electrode 162 or the drain electrode 163 electrically connects with the n-type electrode 145. When the n-type electrode 145 is a metal block, the n-type electrode 145 is formed on the n-type semiconductor layer 144 and is located at a lateral side of the n-type semiconductor layer 144 close to the thin film transistor 16, and the n-type electrode 145 electrically connects with the source electrode 162 or the drain electrode 163. When the n-type electrode 145 is a metal film, and the n-type electrode 145 is formed on the buffer layer 122, the source electrode 162 or the drain electrode 163 extends to connect with the n-type electrode 145.

When the n-type semiconductor layer 144 is a metal oxide semiconductor, the source electrode 162 or the drain electrode 163 electrically connects with the n-type semiconductor layer 144. When the n-type semiconductor layer 144 is a transparent metal oxide semiconductor, the source electrode 162 or the drain electrode 163 electrically connects with the n-type transparent electrode. Such that, the source electrode 162 or the drain electrode 163 may electrically connect with the n-type semiconductor layer 144 or the n-type electrode 145 of the solid state lighting element 14.

The thin film transistor 16 is a poly-silicon thin film transistor or an oxide semiconductor thin film transistor. The active layer 165 of the thin film transistor 16 is a metal oxide semiconductor, a low temperature poly-silicon (LTPS), or an amorphous silicon (a-Si). The metal oxide semiconductor is an amorphous metal oxide semiconductor, poly-silicon metal oxide semiconductor, crystalline metal oxide semiconductor, microcrystalline metal oxide semiconductor, or a nano metal oxide semiconductor. The active layer 165 of the thin film transistor 16 contains In, Ca, Al, Zn, Cd, Ca, Mg, Sn or Pb. Preferably, the active layer 165 is an IGZO (indium gallium zinc oxide) layer. The material for forming the active layer 165 can also be used for forming the current spreading layer 147 of the solid state lighting element 14 which can be transparent.

The gate insulation layer 164 of the thin film transistor 16 can be made of SiOₓ, SiON, SiNₓ, HfOₓ, AlOₓ, Ta₂O₅ or BaSrTiOₓ. At least one of the source electrode 162 and the drain electrode 163 is a transparent oxide electrode, or a metal electrode, or a transparent nonmetallic electrode. The transparent oxide electrode includes ITO (indium tin oxide), IZO (indium zinc oxide), IGZO, AZO (Al-doped Zn Oxide), or ATO (antimony tin oxide). The metal electrode contains one composition of nickel (Ni), titanium (Ti), chromium (Cr), aluminum (Al), gold (Au), silver (Ag), molybdenum (Mo), copper (Cu), platinum (Pt), palladium (Pd), cobalt (Co), tungsten (W), or an alloy thereof. The transparent nonmetallic electrode is made of graphene, carbon nanotubes (CNT) or graphite powder.

According to the first embodiment of the active matrix solid state light display 10, since the solid state lighting element 14 is made of an oxide semiconductor, a nitride semiconductor, a phosphide semiconductor, an arsenide semiconductor or a compound semiconductor, the deterioration problem in manufacturing process is avoided because of the properties of the semiconductors which are not so easily affected by the environmental conditions, and the stability and the reliability of the active matrix solid state light display 10 is maintained.

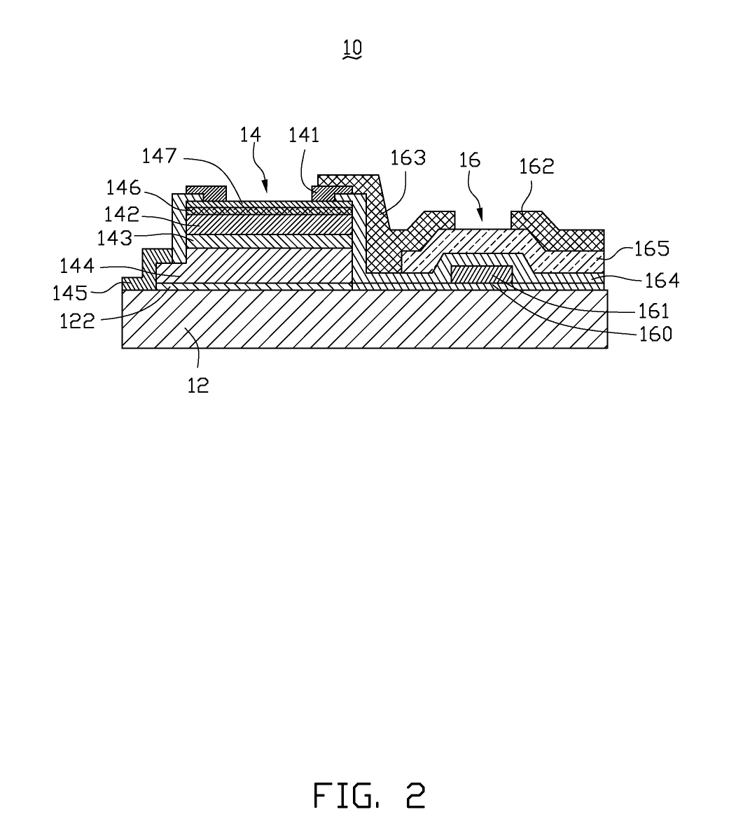

Alternatively, according to the second embodiment, as shown in FIG. 2, the source electrode 162 or the drain electrode 163 electrically connecting with the solid state lighting element 14 is obtained by the source electrode 162 or the drain electrode 163 electrically connecting with the p-type semiconductor layer 142 or the p-type electrode 141. Referring to FIG. 2, the drain electrode 163 electrically connects with the p-type electrode 141. The gate insulation layer 164 is located on the substrate 12, and extends along a thickness direction of the solid state lighting element 14 to insulate the drain electrode 163 of the thin film transistor 16 from other layers (such as the n-type semiconductor layer 144, the light emitting layer 143) of the solid state lighting element 14. The drain electrode 163 extends along the gate insulation layer 164 to contact the p-type electrode 141. Furthermore, the n-type electrode 145 is formed on the substrate 12 and located at an outer side of the n-type semiconductor layer 144 and contacts the n-type semiconductor layer 144. In this embodiment, the n-type electrode 145 is a metal block or a metal film.

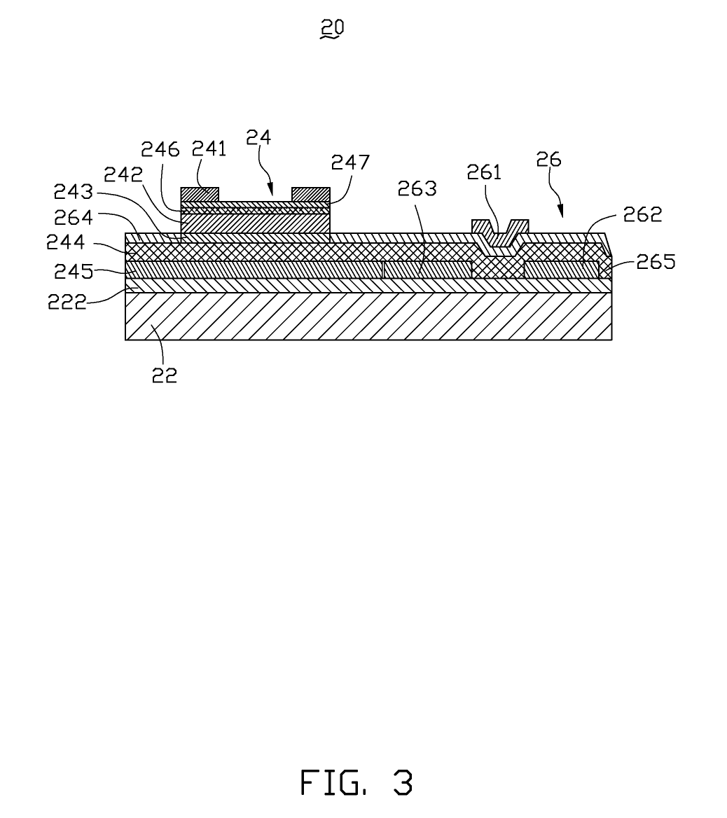

Referring to FIG. 3 an active matrix solid state light display 20 according to a third embodiment is provided. The solid state light display 20 includes a substrate 22, a plurality of solid state lighting elements 24 (only one is shown), and a plurality of thin film transistors 26 (only one is shown). An insulation layer 222 is formed on a top surface of the substrate 22. The solid state lighting element 24 and the thin film transistor 26 are formed on the insulation layer 222. The solid state lighting element 24 is adjacent to the thin film transistor 26.

The solid state lighting element 24 is a P-N type light emitting diode. The solid state lighting element 24 includes a p-type electrode 241, a p-type semiconductor layer 242, a light emitting layer 243, an oxide semiconductor layer 244 and an n-type electrode 245. In addition, a contact layer 246 and a current spreading layer 247 are located between the p-type semiconductor layer 242 and the p-type electrode 241.

The n-type electrode 245 of the solid state lighting element 24 is a metal film formed on the insulation layer 222 on the substrate 22. The source electrode 262 and the drain electrode 263 are located on the insulation layer 222 on the substrate 22, and are adjacent to the n-type electrode 245. The drain electrode 263 electrically connects with the n-type electrode 245. The oxide semiconductor layer 244 is located on the n-type electrode 245, the source electrode 262, and the drain electrode 263, and covers the n-type electrode 245, the source electrode 262, and the drain electrode 263. In this embodiment, the oxide semiconductor layer 244 and the active layer 265 are formed as a single piece. An gate insulation layer 264 is located on the active layer 265. The gate electrode 261 is located on the gate insulation layer 264.

The light emitting layer 243, the p-type semiconductor layer 242, the contact layer 246, the current spreading layer 247 and the p-type electrode 241 are sequentially formed on the oxide semiconductor layer 244 from a bottom-to-top direction. In this embodiment, the solid state lighting element 24 electrically connects with the thin film transistor 26 by a way of the n-type electrode 245 electrically connecting with the source electrode 262 or the drain electrode 263.

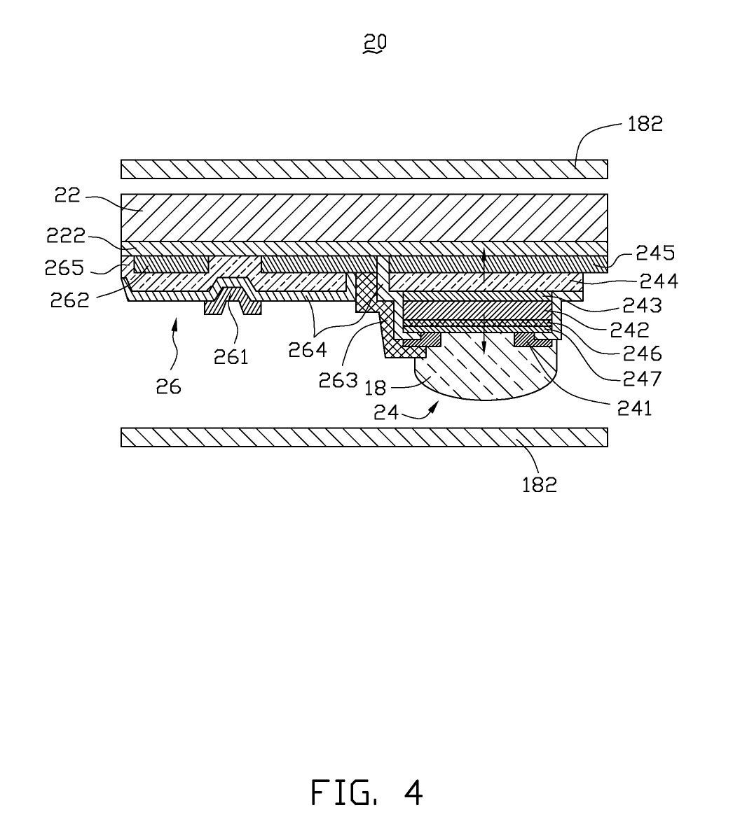

In a fourth embodiment as shown in FIG. 4, the gate insulation layer 264 is used to insulate the n-type electrode 245 from the source electrode 262 or the drain electrode 263. The source electrode 262 or the drain electrode 263 electrically connects with the p-type electrode 241 formed on the solid state lighting element 24 (shown in FIG. 4).

The solid state lighting element 24 further includes a phosphor layer 18. The phosphor layer 18 is formed on the solid state lighting element 24. The phosphor layer 18 is formed on the p-type semiconductor layer 242 to form an encapsulation layer, which covers the top of the solid state lighting element 24. The phosphor layer 18 is excited by primary light emitted from the solid state lighting element 24 to emit secondary light with a different color which mixes with the primary light to generate white light.

A color filter (not shown) can also be provided to be located on the phosphor layer 18 to filter the white light into light of different colors, such as red light, green light and blue light.

The solid state lighting element 24 may emit ultraviolet light, blue light, blue-green light, green light or red light, matching with the colors of the phosphor layer 18. Preferably, the solid state lighting element 24 emits blue light to match with the phosphor layer 18 having green and red fluorescent powder therein; or the solid state lighting element 24 emits ultraviolet light to match with the phosphor layer 18 having red, green and blue fluorescent powder therein.

The phosphor layer 18 may be a plate 182, and the plate 182 is located at an outer side of the solid state light display 20. For example, the plate 182 is located at a same side with the solid state lighting element 24, or two plates 182 which are located at opposite sides of the substrate 22. That is, the plate 182 is located on a light path of the solid state light display 20 and separated from the solid state light display 10 to form a remote phosphor structure.

According to the active matrix solid state light display in this disclosure, because of the material properties of the solid state lighting element, the problem of degradation of organic materials in the manufacturing process of solid state light display can be effectively solved, and the stability of the solid state light display is maintained, and the service life is also extended.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. An active matrix solid state light display, comprising:
a substrate;
a plurality of solid state lighting elements; and
a plurality of thin film transistors;
wherein a buffer layer is formed on the substrate, the solid state lighting elements are formed on the buffer layer, and the thin film transistors are formed on the substrate, each thin film transistor is located at a lateral side of each solid state lighting element, each solid state lighting element is a light emitting diode, each thin film transistor electrically connects with each solid state lighting element by a way of a source electrode or a drain electrode of each thin film transistor connecting with each solid state lighting element.

2. The active matrix solid state light display of claim 1, wherein the buffer layer is electrically insulated, and the buffer layer is made of at least one of LT-AlInGaN (Low Temperature AlInGaN), SiOₓ, SiNₓ, SiON, HfOₓ, AlOₓ, TaOₓ, or BasrTiOₓ.

3. The active matrix solid state light display of claim 1, wherein the substrate is made of sapphire, silicon, silicon on insulator (SOI), glass, GaN, ZnO or plastic.

4. The active matrix solid state light display of claim 1, wherein each solid state lighting element is an oxide semiconductor, an nitride semiconductor, a phosphide semiconductor, an arsenide semiconductor, or a compound semiconductor including III-V semiconductors, II-VI semiconductors, or IV-IV semiconductors.

5. The active matrix solid state light display of claim 1, wherein each solid state lighting element is a p-n type light emitting diode, and includes a p-type electrode, a p-type semiconductor layer, a light emitting layer, an n-type semiconductor layer and an n-type electrode, the n-type semiconductor layer is formed on the buffer layer, the light emitting layer is formed on the n-type semiconductor layer, the p-type semiconductor layer is formed on the light emitting layer, the p-type electrode is formed on the p-type semiconductor layer, and the n-type electrode is formed on the n-type semiconductor layer.

6. The active matrix solid state light display of claim 5, wherein the n-type semiconductor layer is a metal oxide semiconductor, the metal oxide semiconductor is ZnO or IGZO to function as a transparent electrode of each solid state lighting element.

7. The active matrix solid state light display of claim 5, wherein the n-type semiconductor layer is a compound semiconductor and the compound semiconductor is ZnSe, GaAs, InGaAlP or AlInGaN selected from the III-V semiconductors.

8. The active matrix solid state light display of claim 5, wherein a contact layer and a current spreading layer are formed between the p-type semiconductor layer and the p-type electrode.

9. The active matrix solid state light display of claim 5, wherein the light emitting layer of each solid state lighting element is made of CdZnMgSeTe, AlGaInP, AlInGaAs, AlInGaN, ZnO, IGZO, or SiGe.

10. The active matrix solid state light display of claim 1, wherein each thin film transistor further comprises a gate electrode, an insulation layer and a gate insulation layer, the insulation layer is located on the substrate, the gate electrode is formed on the insulation layer, the gate insulation layer is formed on the gate electrode, an active layer is formed on the gate insulation layer, and the source electrode and the drain electrode are formed on the active layer.

11. The active matrix solid state light display of claim 10, wherein the source electrode or the drain electrode electrically connects with the n-type semiconductor layer, or the p-type semiconductor layer, or the n-type electrode, or the p-type electrode.

12. The active matrix solid state light display of claim 10, wherein the active layer of each thin film transistor is made of a metal oxide semiconductor, a low temperature poly-silicon, or an amorphous silicon, the metal oxide semiconductor is an amorphous metal oxide semiconductor, poly-silicon metal oxide semiconductor, crystalline metal oxide semiconductor, microcrystalline metal oxide semiconductor, or a nano metal oxide semiconductor.

13. The active matrix solid state light display of claim 12, wherein the active layer contains In, Ca, Al, Zn, Cd, Ca, Mg, Sn or Pb.

14. The active matrix solid state light display of claim 13, wherein the active layer is made of IGZO, which is a material also for forming a current spreading layer of each solid state lighting element.

15. The active matrix solid state light display of claim 10, wherein the gate insulation layer is made of SiOₓ, SiON, SiNₓ, HfOₓ, AlOₓ, Ta₂O₅ or BaSrTiOₓ.

16. The active matrix solid state light display of claim 10, wherein at least one of the source electrode and the drain electrode comprises a transparent oxide electrode, or a metal electrode, or a transparent nonmetallic electrode.

17. The active matrix solid state light display of claim 16, wherein the transparent oxide electrode is ITO, IZO, IGZO, AZO, or ATO.

18. The active matrix solid state light display of claim 16, wherein the metal electrode contains one composition of Ni, Ti, Cr, Al, Au, Ag, Mo, Cu, Pt, Pd, Co, W, or an alloy thereof.

19. The active matrix solid state light display of claim 16, wherein the transparent nonmetallic electrode is made of graphene, carbon nanotubes (CNT) or graphite powder.

20. The active matrix solid state light display of claim 1, wherein each solid state lighting element is a p-n type light emitting diode, and includes a p-type electrode, a p-type semiconductor layer, a light emitting layer, an oxide semiconductor layer and an n-type electrode, the n-type electrode is formed on an insulation layer on the substrate, the oxide semiconductor layer is formed on the n-type electrode, the light emitting layer, the p-type semiconductor layer and the p-type electrode are sequentially formed on the oxide semiconductor layer.

21. The active matrix solid state light display of claim 20, wherein a contact layer and a current spreading layer are located between the p-type semiconductor layer and the p-type electrode.

22. The active matrix solid state light display of claim 20, wherein the source electrode and the drain electrode of each thin film transistor are formed on an insulation layer formed on the substrate, and one of the source electrode and the drain electrode electrically connects with the n-type electrode adjacent to the drain electrode.

23. The active matrix solid state light display of claim 20, wherein the oxide semiconductor and the active layer of each thin film transistor are formed as a single piece, an gate insulation layer is formed on the active layer, and the gate electrode is formed on the gate insulation layer.

24. The active matrix solid state light display of claim 1 further comprising a phosphor layer, wherein the phosphor layer is located on each solid state lighting element.

25. The active matrix solid state light display of claim 24, wherein the phosphor layer includes fluorescent powder therein.

26. The active matrix solid state light display of claim 24, wherein a color filter is located over the phosphor layer.
